(19) United States
(12) Patent Application Publication
(10) Pub. No.: US 2025/0096018 A1
(43) Pub. Date: Mar. 20, 2025

(54) SUBSTRATE PROCESSING APPARATUS AND SUBSTRATE PROCESSING METHOD

(71) Applicant: SEMES CO., LTD., Cheonan-si (KR)

(72) Inventors: Changhwa JEONG, Cheonan-si (KR); Jungsoo LEE, Cheonan-si (KR); Youngkyu OH, Cheonan-si (KR); Chungoh HONG, Cheonan-si (KR); Jiyun AHN, Cheonan-si (KR)

(73) Assignee: SEMES CO., LTD., Cheonan-si (KR)

(21) Appl. No.: 18/811,189

(22) Filed: Aug. 21, 2024

(30) Foreign Application Priority Data
Sep. 20, 2023 (KR) 10-2023-0125269

(51) Int. Cl. H01L 21/67; H01L 21/677; H01L 21/68

(52) U.S. Cl. CPC H01L 21/6715; H01L 21/67742; H01L 21/67745; H01L 21/68

(57) ABSTRACT

A substrate processing apparatus includes an loading stage configured to receive first and second substrates and including a first substrate alignment portion for aligning the first substrate and a second substrate alignment portion for aligning the second substrate, the first substrate alignment portion being spaced apart from the first substrate alignment portion; an coating stage configured to sequentially receive the first substrate and the second substrate from the loading stage and including a first discharge nozzle for discharging a first chemical solution onto the first substrate and a second discharge nozzle for discharging a second chemical solution onto the second substrate; and an unloading stage configured to sequentially unload the first substrate and the second substrate from the coating stage.

### CROSS-REFERENCE TO RELATED APPLICATION

This application claims priority under 35 USC § 119 to Korean Patent Application No. 10-2023-0125269 filed on Sep. 20, 2023 in the Korean Intellectual Property Office KIPO, the entire disclosure of which is incorporated herein by reference.

### BACKGROUND

### 1. Field

Embodiments of the present disclosure relate to a substrate processing apparatus and a substrate processing method, and more particularly, to a substrate processing apparatus and a substrate processing method for applying a chemical solution such as photoresist on a substrate.

### 2. Description of the Related Art

In a process of applying a chemical solution on a substrate such as a liquid crystal display device, an organic light-emitting display device, etc., the chemical solution may be applied on a glass plate or a glass plate half Coating equipment may have a process space capable of coating one plate. When coating one plate within the process space of the coating equipment, there is a problem that space utilization is reduced and the process time (tact time) increases.

### SUMMARY

One object of the present disclosure is to provide a substrate processing apparatus capable of continuously performing coating processes on a plurality of half plates.

Another object of the present disclosure is to provide a substrate processing method using the substrate processing apparatus.

According to example embodiments, a substrate processing apparatus includes an loading stage configured to receive first and second substrates, the loading stage including a first substrate alignment portion for aligning the first substrate and a second substrate alignment portion for aligning the second substrate, the first substrate alignment portion being spaced apart from the first substrate alignment portion; an coating stage configured to sequentially receive the first substrate and the second substrate from the loading stage, the coating stage including a first discharge nozzle for discharging a first chemical solution onto the first substrate and a second discharge nozzle for discharging a second chemical solution onto the second substrate; and an unloading stage configured to sequentially unload the first substrate and the second substrate from the coating stage.

In example embodiments, the substrate processing apparatus may further include a transfer device configured to sequentially transferring the first and second substrates to the loading stage.

In example embodiments, the transfer device may further include a plurality of rollers that are aligned on one side of the loading stage and rotate to move the first and second substrates.

In example embodiments, the transfer device may further include a robot arm for transferring the first and second substrates, and the loading stage may further include a plurality of support pins for receiving the first and second substrates from the robot arm, respectively.

In example embodiments, the first substrate alignment portion may include a plurality of first central pins provided in a central region of the loading stage and a plurality of first peripheral pins provided in a first peripheral region adjacent to one side of the central region, and the second substrate alignment portion may include a plurality of second central pins provided in the central region of the loading stage, and a plurality of second peripheral pins provided in a second peripheral region adjacent to the other side opposite to the one side of the central region.

In example embodiments, the first and second central pins may be arranged alternately with each other.

In example embodiments, the loading stage may align a third substrate that is larger than each of the first and second substrates, through the first and second peripheral pins.

In example embodiments, the first and second central pins and the first and second peripheral pins may be driven to move up and down and left and right to align each of the first and second substrates.

In example embodiments, when one of the first and second discharge nozzles is driven, the other discharge nozzle may stop driving.

In example embodiments, the first discharge nozzle may be provided adjacent to the loading stage, and the second discharge nozzle may be provided adjacent to the unloading stage.

According to example embodiments, a substrate processing apparatus includes a transfer device configured to transfer first and second half plates in order to perform a coating process; a loading stage configured to receive the first and second half plates from the transfer device, the loading stage including a first substrate alignment portion for aligning the first plate and a second substrate alignment portion for aligning the second plate, the second substrate alignment portion being arranged to be spaced apart from the first substrate alignment portion; a coating stage configured to sequentially receive the first half plate and the second half plate from the loading stage, the coating stage including a first discharge nozzle for discharging a first chemical solution onto the first half plate and a second discharge nozzle for discharging a second chemical solution onto the second half plate; and a loading stage configured to sequentially unload the first half plate and the second half plate from the loading stage.

In example embodiments, the transfer device may further include a plurality of rollers that are aligned on one side of the loading stage and rotate to move the first and second half plates.

In example embodiments, the transfer device may further include a robot arm for transferring the first and second half plates, and the loading stage may further include a plurality of support pins for receiving the first and second half plates from the robot arm, respectively.

In example embodiments, the first substrate alignment portion may include a plurality of first central pins provided in a central region of the loading stage and a plurality of first peripheral pins provided in a first peripheral region adjacent to one side of the central region, and the second substrate alignment portion may include a plurality of second central pins provided in the central region of the loading stage and a plurality of second peripheral pins provided in a second peripheral region adjacent to the other side opposite to the one side of the central region.

In example embodiments, the first and second central pins may be arranged alternately.

In example embodiments, the loading stage may align a substrate that is larger than each of the first and second half plates, through the first and second peripheral pins.

In example embodiments, the first and second central pins and the first and second peripheral pins may be driven to move up and down and left and right to align each of the first and second half plates.

In example embodiments, when one of the first and second discharge nozzles is driven, the other discharge nozzle may stop driving.

In example embodiments, the first discharge nozzle may be provided adjacent to the loading stage, and the second discharge nozzle may be provided adjacent to the unloading stage.

According to example embodiments, a substrate processing apparatus may include a transfer device configured to transfer first and second half plates in order to perform a coating process; a loading stage configured to receive the first and second half plates from the transfer device, the loading stage having a central region and first and second peripheral regions in both sides of the central region, the loading stage including a first substrate alignment portion and a second substrate alignment portion, wherein the first substrate alignment portion aligns the first half plate through a plurality of first central pins provided in the central region and a plurality of first peripheral pins provided in the first peripheral region, wherein the second substrate alignment portion aligns the second half plate through a plurality of second central pins provided in the central region and a plurality of second peripheral pins provided in the second peripheral region, the second central pins being arranged alternately with the first central pins; a coating stage configured to sequentially receive the first and second half plates from the loading stage, the coating stage having a first discharge nozzle for discharging a first chemical solution onto the first half plate and a second discharge nozzle for discharging a second chemical solution onto the second half plate, the coating stage being configured to selectively drive one of the first and second discharge nozzles; and an unloading stage configured to sequentially unload the first half plate and the second half plate from the coating stage to the outside.

According to example embodiments, a substrate processing apparatus may include a loading stage configured to receive first and second substrate and including a first substrate alignment portion for aligning the first substrate and a second substrate alignment portion for aligning the second substrate, the second substrate alignment portion being arranged to be spaced apart from the first substrate alignment portion, a coating stage configured to sequentially receive the first and second substrate from the loading stage and having a first discharge nozzle for discharging a first chemical solution onto the first substrate and a second discharge nozzle for discharging a second chemical solution onto the second substrate, and an unloading stage configured to sequentially unload the first substrate and the second substrate from the coating stage to the outside.

Accordingly, the loading stage may align the first and second substrates simultaneously, through the first and second substrate alignment portions. The first and second substrates may be a plurality of half plates that are cut from a single display substrate. Since the loading stage may sequentially provide the plurality of half plates onto the coating stage, the substrate processing apparatus may continuously perform the coating processes on the plurality of half plates, and may reduce the time required for aligning the plurality of half plates.

In addition, the coating stage may have the first and second discharge nozzles for respectively discharging the first and second chemical solutions onto the first and second substrates. The first and second substrates may be sequentially provided from the loading stage to the coating stage, and the coating processes may be sequentially performed on the first and second substrates through the first and second discharge nozzles, respectively.

Since the loading stage simultaneously receives the first and second substrates, and the coating stage sequentially performs the coating processes on the first and second substrates, the substrate processing apparatus may reduce the process time (tact time).

However, effects of the present disclosure are not limited to the above-described effects, and may be variously expanded without departing from the idea and scope of the present disclosure.

### BRIEF DESCRIPTION OF THE DRAWINGS

FIG. 1 is a plan view illustrating a substrate processing system in accordance with example embodiments.

FIG. 2 is a perspective view illustrating the substrate processing apparatus of FIG. 1 according to example embodiments.

FIG. 3 is a plan view illustrating the substrate processing apparatus of FIG. 2.

FIG. 4 is a front view illustrating the substrate processing apparatus of FIG. 2.

FIGS. 5 to 7 are views illustrating a step of arranging first and second substrates.

FIGS. 8 to 10 are views illustrating a step of applying a chemical solution on the first and second substrates.

FIGS. 11 and 12 are views illustrating a step of placing a third substrate and discharging a solution on the third substrate.

FIG. 13 is a plan view illustrating a substrate processing apparatus including a transfer device having a robot arm in according with example embodiments.

FIGS. 14 to 17 are views illustrating a step of placing first and second substrates through the robot arm of FIG. 13.

### DETAILED DESCRIPTION OF THE EMBODIMENTS

Hereinafter, example embodiments of the present disclosure will be described in more detail with reference to the accompanying drawings.

Since various modifications can be made to the present disclosure, and the present disclosure may have various forms, embodiments will be described in detail through the detailed description. This, however, is by no means to restrict the present disclosure to a specific disclosed form, and the present disclosure shall be construed as encompassing all modifications, equivalents, and substitutes included in the idea and technical scope of the present disclosure.

Terms used herein are intended to describe certain embodiments only, and shall by no means restrict the present disclosure. Unless the context explicitly indicates otherwise, expressions in a singular form include a meaning of a plural form. In the present disclosure, a term such as “comprising” or “including” is intended to designate the presence of characteristics, numbers, steps, operations, elements, parts, or combinations thereof described in the present disclosure, and shall not be construed to preclude any possibility of presence or addition of one or more other characteristics, numbers, steps, operations, elements, parts, or combinations thereof.

While describing each drawing, similar reference numerals will be used for similar elements. Terms such as “first” and “second” may be used to describe various elements, but the elements are not limited by the terms, and the terms may be used only to distinguish one element from another element.

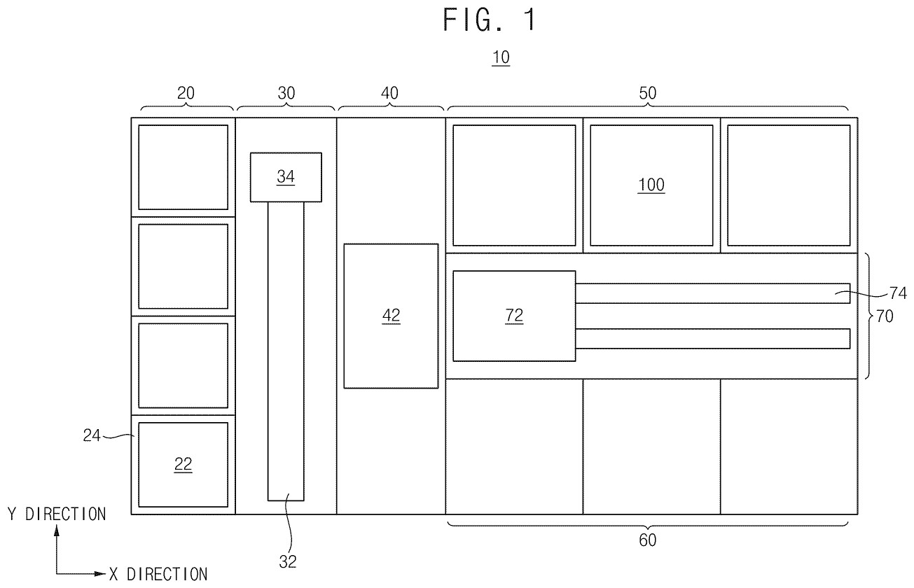

FIG. 1 is a plan view illustrating a substrate processing system in accordance with example embodiments.

Referring to FIG. 1, a substrate processing system 10 may include a load port 20 and an index module 30 that are configured to load and unload substrates, and a process module arranged in one side of the index module 30 and configured to sequentially perform semiconductor processes on the substrates. For example, the substrate may include a liquid crystal display device, an organic light-emitting display device, a semiconductor wafer, etc.

The load port 20, the index module 30, and the process module may be arranged along a first direction (X direction). The process module may include a buffer chamber 40, a first process chamber 50, a second process chamber 60, and a transfer chamber 70.

In example embodiments, the substrate processing system 10 may perform a semiconductor process, such as a development process, a drying process, etc. on a substrate on which an exposure process and a soft bake process have been performed. For example, the first process chamber 50a may perform a coating process in which a chemical process, a rinsing process and an organic solvent process are sequentially performed, and the second process chamber 60 may perform a drying process using a supercritical fluid.

As illustrated in FIG. 1, the load port 20 may include a support plate 24 for supporting a carrier 22 including a plurality of substrates stored therein. The load port 20 may be a port on which the substrates are loaded or unloaded, and a plurality of the support plates 24 may be arranged in the load port 20 along a second direction (Y direction) perpendicular to the first direction.

The index module 30 may include an index robot 34 that is movable along an index rail 32 extending in the Y direction within an index frame. The index robot 34 may transfer the substrates between the carrier 22 on the support plate 24 and the process module. The index robot 34 may include a base, a robot hand, and a vertical guide. The base may be provided to be movable in the Y direction along the index rail 32, the vertical guide may extend vertically on the base, and the robot hand may be movable in the vertical direction along the vertical guide.

The process module may be arranged in one side of the index module 30. The buffer chamber 40 may be arranged in one side of the index frame of the index module 30. The buffer chamber 40 may include a plurality of buffers 42 for temporarily storing a plurality of substrates, respectively. The plurality of buffers 42 may be arranged vertically to be spaced apart from each other. The buffer 42 may include a support plate for supporting the substrate. The buffer chamber 40 may further include a buffer robot that is provided in one side of the buffers 42 and transfer the substrate between the buffers 42.

The transfer chamber 70 may extend in a direction parallel to the X direction from the buffer chamber 40. The first process chambers 50 may be arranged in one side of the transfer chamber 70. The second process chambers 60 may be arranged in the other side of the transfer chamber 70. The first process chambers 50 may be arranged along the X direction. The second process chambers 60 may be arranged along the X direction. Each of the first process chambers 50 may include a plurality of substrate processing apparatuses 100 that are vertically stacked in multiple stages. Each of the second process chambers 60 may include a plurality of drying apparatuses that are vertically stacked in multiple stages.

The buffer chamber 40 may provide a space where a substrate to be transferred from the index module 30 to the first process chamber 50 and a substrate to be transferred from the second process chamber 60 to the index module 30 temporarily stay. In the first process chamber 50, a development process may be performed the substrate. In the first process chamber 50, a development process may be performed the substrate on which an exposure process has been performed. In the second process chamber 60, a drying process may be performed on the substrate on which the development process has been performed.

The transfer chamber 70 for transferring the substrate may be provided between the first process chamber 50 and the second process chamber 60. A transfer robot 72 may transfer the substrate while moving along a transfer rail 74 extending in the X direction. The transfer robot 72 may be installed to be movable vertically along a vertical guide.

The transfer robot 72 may transfer the substrate placed in the buffer chamber 40 to the first process chamber 50. The transfer robot 72 may transfer the substrate on which the development process has been performed in the first process chamber 50 to the second process chamber 60. The transfer robot 72 may transfer the substrate on which the development process has been performed in the second process chamber 60 to the buffer chamber 40.

In example embodiments, a plurality of the first process chambers 50 may be arranged in the X direction. The type of the chemical used in each of the first process chambers 50 may be different from each other. As an example, the chemical may be a negative tone developer. The chemical may include n-butyl acetate. The first process chamber 50 may include a developing apparatus for applying a developing solution on a substrate on which an exposure process has been performed to perform a developing process.

A plurality of the second process chambers 60 may be arranged in the X direction. The second process chamber 60 may perform a drying process of supplying a high-pressure fluid on a substrate on which the chemical has been applied. For example, a developing process may be performed on a substrate in the first process chamber 50, and a drying process may be performed in the second process chamber 60.

Alternatively, in the first process chamber 50, a chemical process, a rinse process, and a first drying process may be sequentially performed on the substrate, and in the second process chamber 60, a second drying process may be performed. In this case, the first drying process may be performed using an organic solvent, and the second drying process may be performed using a supercritical fluid. Isopropyl alcohol IPA liquid may be used as the organic solvent, and carbon dioxide (CO₂) may be used as the supercritical fluid. Alternatively, the first drying process may be omitted in the first process chamber 50.

The arrangements of the load port, the index module, and the process module, and the arrangements and number of the first and second process chambers are illustrated as examples, and it will be understood that the present inventive concept is not limited thereto.

Hereinafter, the substrate processing apparatus 100 of the first process chamber 50 will be described in detail.

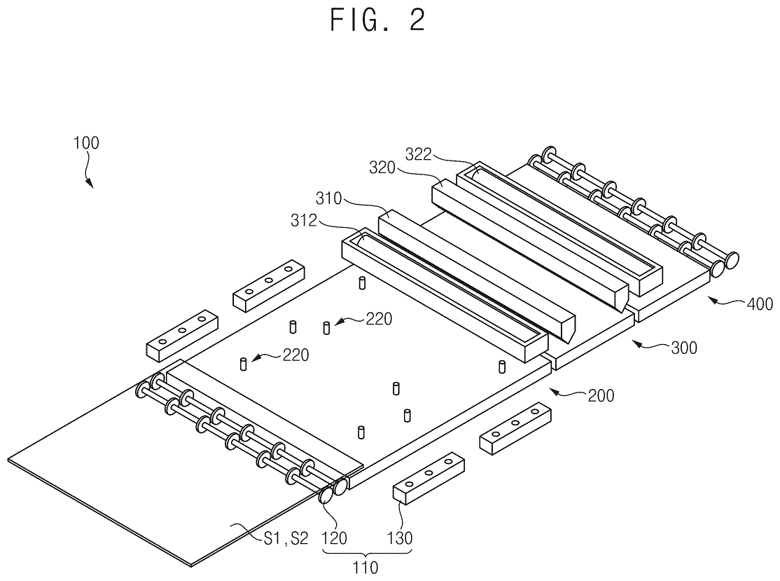

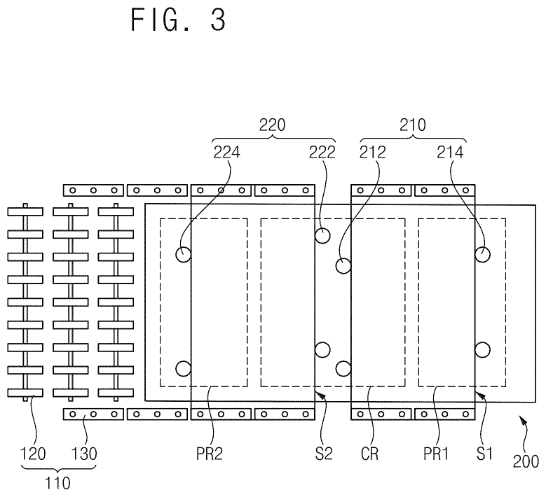

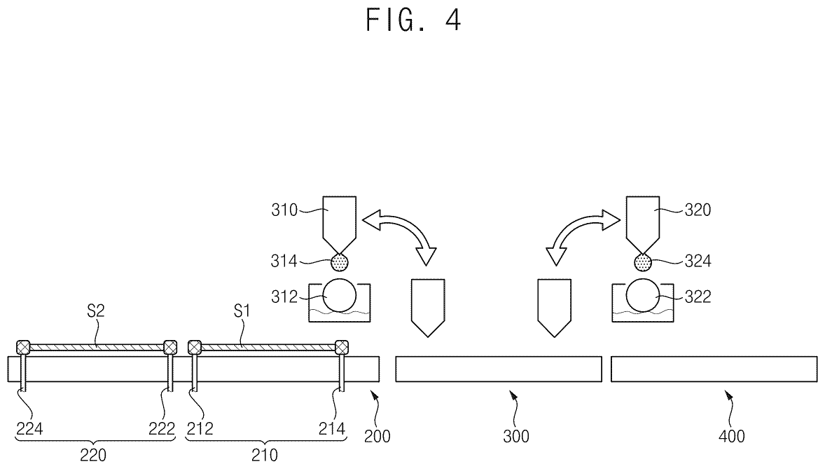

FIG. 2 is a perspective view illustrating the substrate processing apparatus of FIG. 1 according to example embodiments. FIG. 3 is a plan view illustrating the substrate processing apparatus of FIG. 2. FIG. 4 is a front view illustrating the substrate processing apparatus of FIG. 2.

Referring to FIGS. 1 to 4, a substrate processing apparatus 100 may include a loading stage 200 configured to receive substrates for performing a coating process, a coating stage 300 configured to apply a chemical on the substrates, and an unloading stage 400 configured to unload the substrates to the outside. The loading stage 200, the coating stage 300, and the unloading stage 400 may be sequentially arranged along one direction for the coating process.

The substrate processing apparatus 100 may provide air and vacuum to lower surfaces of the substrates S1, S2 to move the substrates in a floating state on the loading stage 200, the coating stage 300, and the removal stage 400. The substrate processing apparatus 100 may precisely control positions of the substrates by controlling the air and the vacuum.

In example embodiments, the substrate may include an original glass plate, two glass half plates having ½ size of the original glass plate by dividing the original glass plate into two, and a substrate having ⅓ size of the original glass plate by dividing the original glass plate into three. In this specification, the half plates may include a first substrate and a second substrate. The original plate may include a third substrate. The size of the third substrate may be greater than the sizes of each of the first and second substrates.

The substrate processing apparatus 100 may perform the coating process on the original plate and the half plate. The substrate processing apparatus as a single facility may perform coating, exposure, development, cleaning, and drying processes on the original plate and the half plate.

The substrate processing apparatus 100 may perform the coating process on one original plate or one half plate. For example, the substrate processing apparatus 100 may accommodate one original plate when two or more of the original plates are transferred from the transfer chamber 70. Alternatively, the substrate processing apparatus 100 may accommodate both of two half plates when the two half plates are transferred from the transfer chamber 70.

In example embodiments, the substrate processing apparatus 100 may further include a transfer device 110 for transferring the substrate. The transfer device 110 may receive the substrate from the transfer chamber 70 of the substrate processing system 10. Alternatively, the transfer device 110 may be provided integrally with the transfer chamber 70. The transfer device 110 may include the same components as the transfer chamber 70. The transfer device 110 may transfer the substrate received from the transfer chamber 70 to the loading stage 200. The transfer device 110 may sequentially transfer the first and second substrates S1, S2 to the loading stage 200. The transport device 110 may include a plurality of rollers 120 that rotate to move the first and second substrates S1, S2, and a plurality of grippers 130 to support the first and second substrates S1, S2, respectively.

The plurality of rollers 120 may be aligned in one side of the loading stage 200. Additionally, the plurality of rollers 120 may be aligned in one side of the loading stage 400. When the substrate is placed on the plurality of rollers 120, the plurality of rollers 120 may rotate to move the substrate.

The plurality of rollers 120 may move the first and second substrates S1, S2 that a preceding process has been completed to the loading stage 200 by roller driving, and may unload the first and second substrates S1, S2 that the chemicals have been applied, from the loading stage 400 to a subsequent process by roller driving.

The grippers 130 may transport the substrates while holding the first and second substrates S1, S2, respectively. Alternatively, the grippers 130 may transport the substrate while supporting lower surfaces of the first and second substrates S1, S2. The grippers 130 may move the first and second substrates S1, S2 in a floating state on the loading stage 200, the coating stage 300, and the unloading stage 400. The grippers 130 may move along both sides of each of the loading stage 200, the coating stage 300, and the unloading stage 400.

In example embodiments, the loading stage 200 may align the first and second substrates S1, S2, respectively. The loading stage 200 may include a first substrate alignment portion 210 to align the first substrate S1 and a second substrate alignment portion 220 to align the second substrate S2. The loading stage 200 may include a central region CR, a first peripheral region PR1 positioned adjacent to one side of the central region CR, and a second peripheral region PR2 positioned adjacent to the other side opposite to the one side. The central region CR may be provided between the first and second peripheral regions PR1, RP2. The first peripheral region PR1 may be provided to face the coating stage 300, and the second peripheral region PR2 may be provided to face the rollers 120.

The first substrate alignment portion 210 may include a plurality of first central pins 212 provided in the central region CR of the loading stage 200 and a plurality of first peripheral pins 214 provided in the first peripheral region PR1. The first central pins 212 and the first peripheral pins 214 may be driven to move up and down and left and right, to align the first substrate S1.

The second substrate alignment portion 220 may include a plurality of second central pins 222 provided in the central region CR of the loading stage 200 and a plurality of second peripheral pins 224 provided in the second peripheral region PR2. The second central pins 222 and the second peripheral pins 224 may be driven to move up and down and left and right, to align the second substrate S2.

The first and second substrate alignment portions 210, 220 may align the first and second substrates S1, S2 respectively, and may simultaneously align the first and second substrates S1, S2. Since the first and second substrate alignment portions 210, 220 simultaneously align the first and second substrates S1, S2, the time required for aligning the first and second substrates S1, S2 may be reduced.

The first and second central pins 212, 222 may be alternately arranged in the central region CR. The second central pins 222 may be arranged between the first central pins 212 in the central region CR. Alternatively, the first central pins 212 may be arranged between the second central pins 222 in the central region CR. Since the first and second central pins 212, 222 are arranged alternately in the central region CR, a distance between the first central pins 212 and a distance between the second central pins 222 may be increased to stably arrange the first and second substrates S1, S2.

The loading stage 200 may align a third substrate, which is greater than each of the first and second substrates S1, S2. The loading stage 200 may align the third substrate by using the first and second peripheral pins 214, 224.

In example embodiments, the coating stage 300 may sequentially receive first and second substrates S1, S2 from the loading stage 200. The coating stage 300 may include first and second discharge nozzles 310, 320 to discharge chemicals onto the substrates. For example, the chemicals may include photoresist.

For example, the coating stage 300 may discharge a first chemical 314 onto the first substrate S1 through the first discharge nozzle 310. The coating stage 300 may discharge a second chemical 324 onto the second substrate S2 through the second discharge nozzle 320. The first and second discharge nozzles 310, 320 may discharge the first and second solutions 314, 324 onto the first and second substrates S1, S2 in an inkjet printing manner, respectively. The first and second discharge nozzles 310, 320 may be arranged to be spaced apart from each other, and the first and second discharge nozzles 310, 320 may discharge the first and second solutions 314, 324 in g units, respectively.

The first and second discharge nozzles 310, 320 may be driven to move between a standby position and a discharging position. The first and second discharge nozzles 310, 320 may apply the first and second solutions 314, 324 at the discharge position respectively, and then return to the standby position. Alternatively, the first and second discharge nozzles 310, 320 may be positioned fixedly at the discharging position.

When one of the first and second discharge nozzles 310, 320 is driven to move, the other discharge nozzle may stop moving. In particular, when the first discharge nozzle 310 discharges the first chemical solution 314 onto the first substrate S1, the second discharge nozzle 320 may stop moving. When the second discharge nozzle 320 discharges the second chemical solution 324 onto the second substrate S2, the first discharge nozzle 310 may stop driving. Since the first and second discharge nozzles 310, 320 are not driven to move at the same time, a collision occurring between the first and second discharge nozzles 310, 320 may be prevented.

The first discharge nozzle 310 may be provided adjacent to the loading stage 200, and the second discharge nozzle 320 may be provided adjacent to the unloading stage 400.

The coating stage 300 may further include a plurality of piezoelectric elements. When the first substrate S1 or the second substrate S2 are positioned on the piezoelectric elements, the first discharge nozzle 310 or the second discharge nozzle 320 may discharge the chemicals. A discharge amount of the first chemical solution discharged from the first discharge nozzle 310 and a discharge amount of the second chemical solution discharged from the second discharge nozzle 320 may be independently controlled by controlling voltages applied to the piezoelectric elements.

The coating stage 300 may further include first and second priming rollers 312, 322 to allow the first and second discharge nozzles 310, 320 to uniformly apply the first and second chemicals. The first and second priming rollers 312, 322 may be provided such that the first and second discharge nozzles 310, 320 uniformly discharge the first and second chemicals 314, 324 respectively. When the first and second discharge nozzles 310, 320 are in a standby state where they do not apply the first and second chemicals 314, 324, the first and second discharge nozzles 310, 320 may move onto the first and second priming rollers 312, 322, respectively.

For example, before the first and second solutions 314, 324 are discharged from the first and second discharge nozzles 310, 320, the first and second discharge nozzles 310, 320 may preliminarily discharge the first and second solutions 314, 324 onto the first and second priming rollers 312, 322 such that beads of the first and second solutions 314, 324 are formed at uniform concentrations and flow rates on discharge end portions of the first and second discharge nozzles 310, 320.

The first priming roller 312 may be provided adjacent to the first discharge nozzle 310, and the second priming roller 322 may be provided adjacent to the second discharge nozzle 320. The first and second priming rollers 312, 322 may be provided at the standby positions, respectively. The first and second discharge nozzles 310, 320 may reciprocally move between the first and second priming rollers 312, 322 and the discharging position.

In example embodiments, the unloading stage 400 may sequentially unload the first and second substrates S1, S2 to which the first and second chemicals 314, 324 are respectively applied. For example, the unloading stage 400 may sequentially unload the first and second substrates S1, S2 to the transfer chamber 70 of the substrate processing system 10.

As mentioned above, the loading stage 200 may align the first and second substrates S1, S2 simultaneously, through the first and second substrate alignment portions 210, 220. The first and second substrates S1, S2 may be a plurality of half plates cut from a single display substrate. Since the loading stage 200 may sequentially provide the plurality of half plates onto the coating stage 300, the substrate processing apparatus 100 may continuously perform the coating processes on the plurality of half plates, and may reduce the time required for aligning the plurality of half plates.

In addition, the coating stage 300 may have the first and second discharge nozzles 310, 320 for respectively discharging the first and second chemicals 314, 324 onto the first and second substrates S1, S2. The first and second substrates S1, S2 may be sequentially provided from the loading stage 200 to the coating stage 300, and the coating processes may be sequentially performed on the first and second substrates S1, S2 through the first and second discharge nozzles 310, 320, respectively.

Since the loading stage 200 simultaneously receives the first and second substrates S1, S2, and the coating stage 300 sequentially performs the coating processes on the first and second substrates S1, S2, the substrate processing apparatus 100 may reduce the process time (tact time).

Hereinafter, a substrate processing method using the substrate processing apparatus of FIG. 2 will be described in detail.

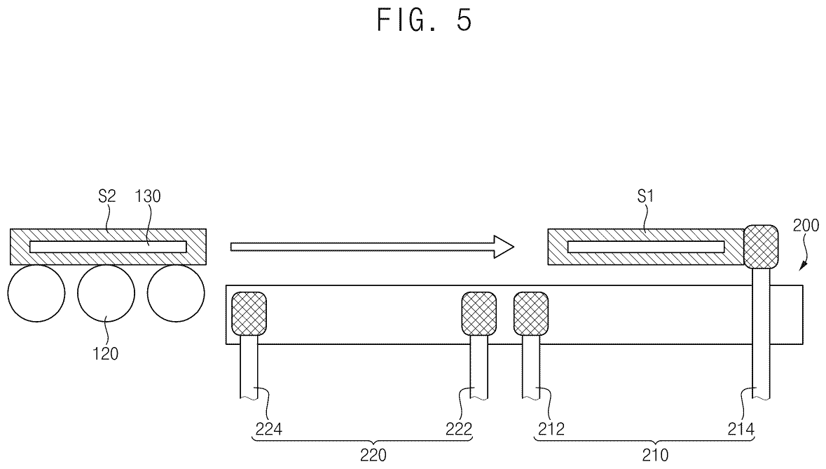

FIGS. 5 to 7 are views illustrating a step of arranging first and second substrates.

Referring to FIGS. 5 to 7, the first and second substrates S1, S2 may be aligned on a loading stage 200 in the substrate processing method.

In example embodiments, the substrate processing method may be a coating process of applying a chemical solution on a substrate such as a liquid crystal display element, an organic light-emitting display element, etc. For example, the first and second substrates S1, S2 may be two separate plates each having ½ size of an original plate by dividing the original plate into two.

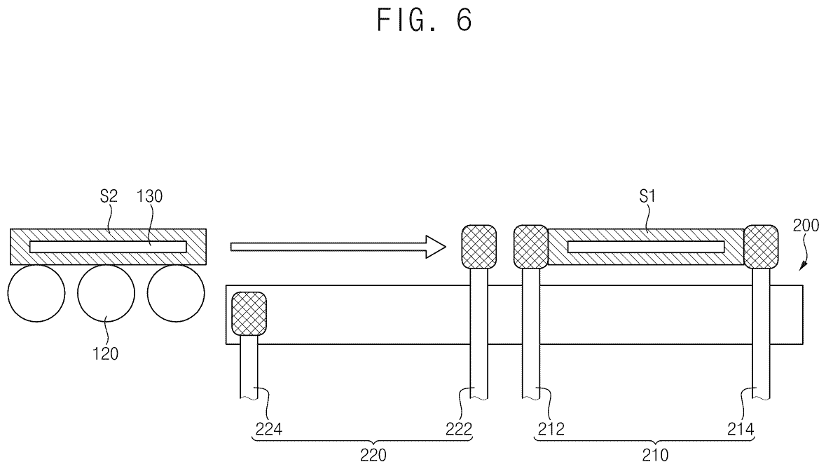

As illustrated in FIGS. 5 and 6, the first substrate S1 may be placed on the loading stage 200. The first substrate S1 may be moved slidably on a plurality of rollers 120 to be loaded onto the loading stage 200. The first substrate S1 may move in a floating state while both sides of the first substrate S1 are supported by grippers 130.

First peripheral pins 214 may be raised to align the first substrate S1. The first peripheral pins 214 may stop the first substrate S1 moving by the grippers 130. One side of the first substrate S1 may be aligned by the first peripheral pins 214.

First central pins 212 may be raised to align the first substrate S1. The other side of the first substrate S1 opposite to the one side may be aligned by the first central pins 212. The first central pins 212 and the first peripheral pins 214 may support the one side and the other side of the first substrate S1, respectively, and may be driven to move up and down and left and right to align the first substrate S1 to a preset position.

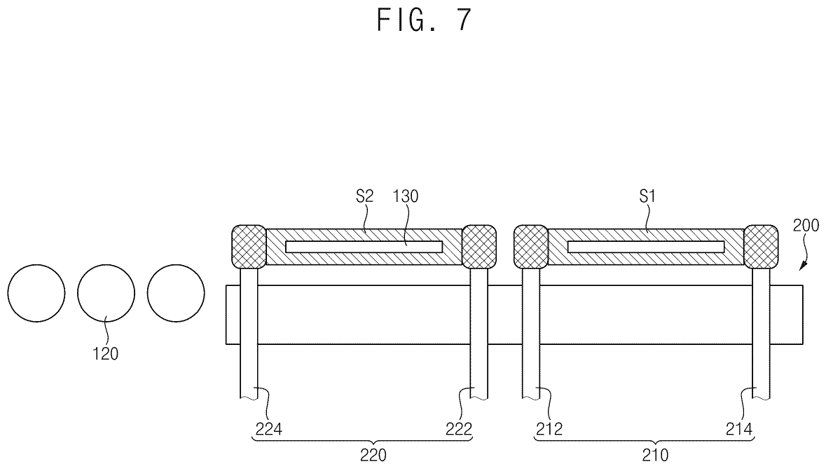

As illustrated in FIG. 6 and FIG. 7, the second substrate S2 may be placed on the loading stage 200. The second substrate S2 may be moved slidably on the plurality of rollers 120 to be loaded onto the loading stage 200. The second substrate S2 may move in a floating state while both sides of the second substrate S2 are supported by the grippers 130.

Second central pins 222 may be raised to align the second substrate S2. The second central pins 222 may stop the second substrate S2 moving by the grippers 130. One side of the second substrate S2 may be aligned by the second central pins 222.

Second peripheral pins 224 may be raised to align the second substrate S2. The other side of the second substrate S2 opposite to the one side may be aligned by the second peripheral pins 224. The second central pins 222 and the second peripheral pins 224 may support the one side and the other side of the second substrate S2, respectively, and may be driven to move up and down and left and right to align the second substrate S2 to a preset position.

The second central pins 222 and the second peripheral pins 224 may be driven independently of the first central pins 212 and the first peripheral pins 214. The second central pins 222 and the second peripheral pins 224 may be arranged to be spaced apart from the first central pins 212 and the first peripheral pins 214. Accordingly, the first and second substrates S1, S2 may be aligned simultaneously on the loading stage 200. Since the first and second substrates S1, S2 are aligned simultaneously on the loading stage 200, the process time (tact time) for performing the coating process on the first and second substrates S1, S2 may be reduced.

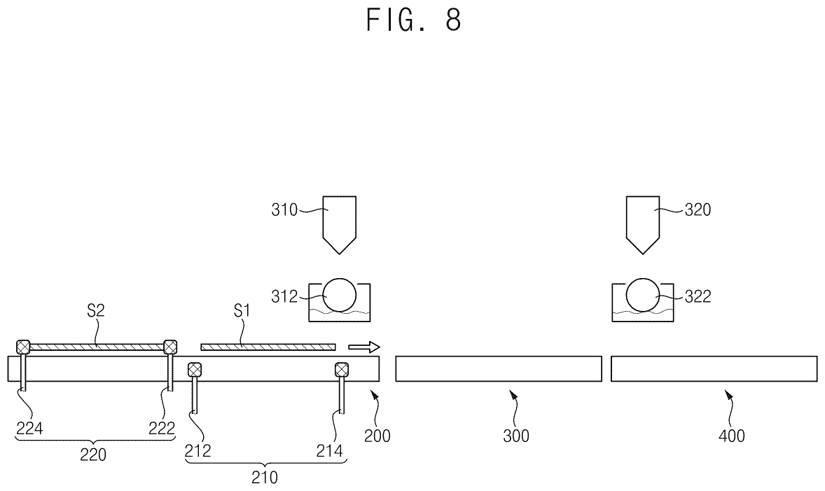

FIGS. 8 to 10 are views illustrating a step of applying a chemical solution on the first and second substrates.

Referring to FIGS. 8 to 10, the first and second substrates S1, S2 whose positions are aligned on the loading stage 200 may be moved onto a coating stage 300 in the substrate processing method. The coating process for the first and second substrates S1, S2 may be performed on the coating stage 300.

As illustrated in FIG. 8, the first substrate S1 may be moved from the loading stage 200 to the coating stage 300. The first substrate S1 may be moved in a floating state by the grippers 130. The first central pins 212 and the first peripheral pins 214 may be lowered and then the first substrate S1 may move. The first substrate S1 may be moved onto the coating stage 300 in an aligned state by the first central pins 212 and the first peripheral pins 214.

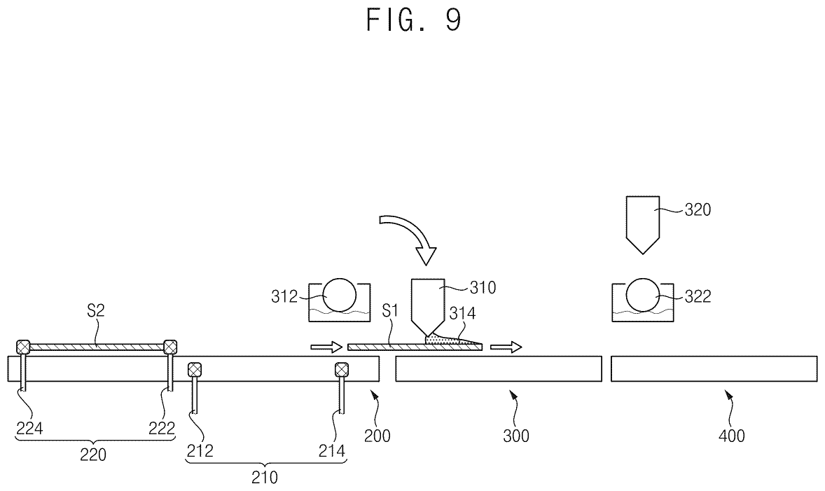

As illustrated in FIG. 9, a first discharge nozzle 310 may discharge the first chemical solution 314 onto the first substrate S1 in an inkjet printing manner. The first discharge nozzle 310 may be driven to move between a first standby position and a first discharging position.

When the first discharge nozzle 310 is positioned at the first standby position, a first priming roller 312 may maintain the first discharge nozzle 310 so that the first discharge nozzle 310 can uniformly discharge the first chemical solution 314. For example, the first discharge nozzle 310 may preliminarily discharge the first chemical solution 314 onto the first priming roller 312 such that beads of the first chemical solution 314 are formed at a uniform concentration and flow rate on a discharge end portion of the first discharge nozzle 310.

When the first substrate S1 is introduced from the loading stage 200 onto the coating stage 300, the first discharge nozzle 310 may move from the first standby position to the first discharging position. The first discharge nozzle 310 may uniformly discharge the first chemical solution 314 onto the first substrate S1 at the first discharging position.

The first discharge nozzle 310 may be provided adjacent to the loading stage 200 and may rapidly discharge the first chemical solution 314 onto the first substrate S1 introduced from the loading stage 200. For example, the first chemical solution 314 may include a photoresist.

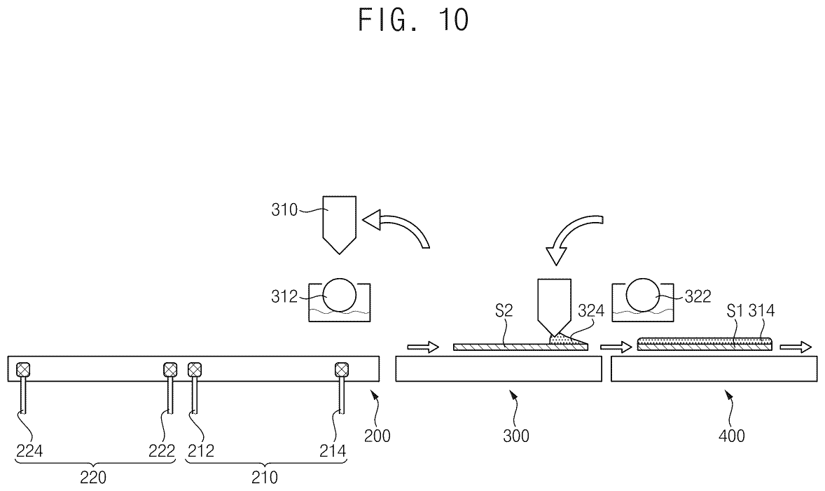

As illustrated in FIG. 10, the second substrate S2 may be moved from the loading stage 200 to the coating stage 300. The second substrate S2 may be moved in a floating state by the grippers 130. The second central pins 222 and the second peripheral pins 224 may be lowered and then the second substrate S2 may move. The second substrate S2 may be moved onto the coating stage 300 in an aligned state by the second central pins 222 and the second peripheral pins 224.

A second discharge nozzle 320 may discharge the second chemical solution 324 onto the second substrate S2 in an inkjet printing manner. The second discharge nozzle 320 may be driven to move between a second standby position and a second discharging position.

When the second discharge nozzle 320 is positioned at the second standby position, a second priming roller 322 may maintain the second discharge nozzle 320 so that the second discharge nozzle 320 can uniformly discharge the second chemical solution 324. For example, the second discharge nozzle 320 may preliminarily discharge the second chemical solution 324 onto the second priming roller 322 such that beads of the second chemical solution 324 are formed at a uniform concentration and flow rate on a discharge end portion of the second discharge nozzle 320.

When the second substrate S2 is introduced from the loading stage 200 onto the coating stage 300, the second discharge nozzle 320 may move from the second standby position to the second discharging position. The second discharge nozzle 320 may uniformly discharge the second chemical solution 324 onto the second substrate S2 at the second discharging position.

The second discharge nozzle 320 may be provided adjacent to the unloading stage 400. When the first discharge nozzle 310 discharges the first chemical solution 314 onto the first substrate S1, the second discharge nozzle 320 may stand by to discharge the second chemical solution 324 onto the second substrate S2.

After the first substrate S1 is moved to the unloading stage 400, the second discharge nozzle 320 may rapidly discharge the second chemical solution 324 onto the second substrate S2 that is introduced from the loading stage 200 to the coating stage 300. For example, the second chemical solution 324 may include a photoresist.

When one of the first and second discharge nozzles 310, 320 is driven, the other discharge nozzle may stop driving. In particular, when the first discharge nozzle 310 discharges the first chemical solution 314 onto the first substrate S1, the second discharge nozzle 320 may stop driving. When the second discharge nozzle 320 discharges the second chemical solution 324 onto the second substrate S2, the first discharge nozzle 310 may stop driving. Since the first and second discharge nozzles 310, 320 are not driven simultaneously, collision occurring between the first and second discharge nozzles 310, 320 may be prevented.

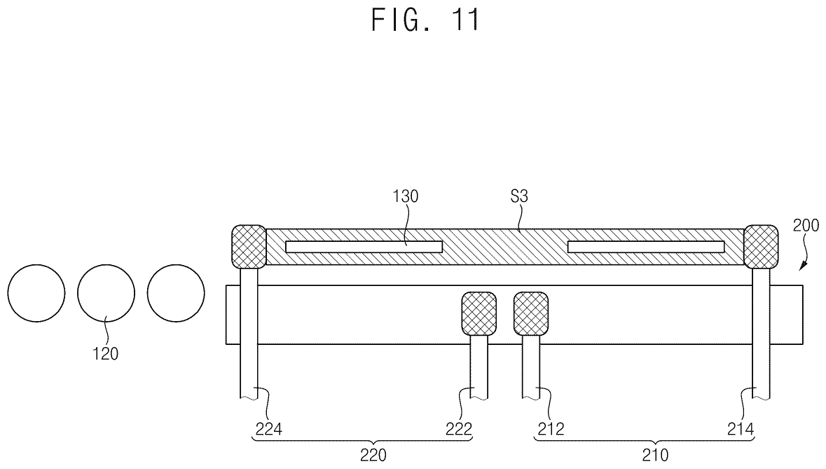

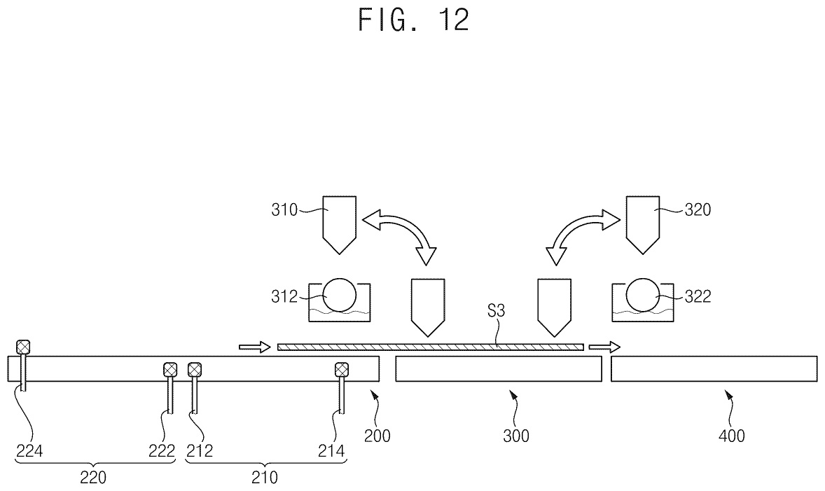

FIGS. 11 and 12 are views illustrating a step of placing a third substrate and discharging a solution on the third substrate.

Referring to FIGS. 11 and 12, a coating process for a third substrate S3 may be performed in the substrate processing method. For example, the third substrate S3 may be the original plate. The third substrate S3 may be larger than each of the first and second substrates S1, S2.

In example embodiments, the third substrate S3 may be aligned on the loading stage 200 and then may be moved onto the coating stage 300, in the substrate processing method. The coating process for the third substrate S3 may be performed on the coating stage 300.

As illustrated in FIG. 11, the third substrate S3 may be placed on the loading stage 200. The third substrate S3 may be moved slidably on the plurality of rollers 120 to be loaded onto the loading stage 200. The third substrate S3 may move in a floating state while both sides of the third substrate S3 are supported by the grippers 130.

The first peripheral pins 214 and the second peripheral pins 224 may be raised to align the third substrate S3. The first peripheral pins 214 may stop the third substrate S3 moving by the grippers 130. One side of the third substrate S3 may be aligned by the first peripheral pins 214.

The second peripheral pins 224 may be raised to align the third substrate S3. The other side of the third substrate S3 opposite to the one side may be aligned by the second peripheral pins 224. The first peripheral pins 214 and the second peripheral pins 224 may support the one side and the other side of the third substrate S3, respectively, and may be driven to move up and down and left and right to align the third substrate S3 to a preset position.

The first peripheral pins 214 and the second peripheral pins 224 may be driven independently of the first central pins 212 and the second central pins 222. Accordingly, the first peripheral pins 214, the first central pins 212, the second peripheral pins 224, and the second central pins 222 may align the substrate regardless of the size of the substrate.

As illustrated in FIG. 12, the third substrate S3 may be moved from the loading stage 200 to the coating stage 300. The third substrate S3 may be moved in a floating state by the grippers 130. The first peripheral pins 214 and the second peripheral pins 224 may be lowered to move the third substrate S3. The third substrate S3 may be moved onto the coating stage 300 in an aligned state by the first peripheral pins 214 and the second peripheral pins 224.

The first and second discharge nozzles 310, 320 may discharge the first and second chemical solutions 314, 324 onto the third substrate S3 in an inkjet printing manner, respectively. The first and second discharge nozzles 310, 320 may selectively discharge the first and second chemical solutions 314, 324 onto the third substrate S3.

When the third substrate S3 is introduced onto the coating stage 300 from the loading stage 200, the first and second discharge nozzles 310, 320 may move to discharge the first and second chemical solutions 314, 324. For example, the first and second chemical solutions 314, 324 may contain the same liquid, or alternatively, the first and second chemical solutions 314, 324 may contain different liquids. When the first chemical solution 314 is discharged onto the third substrate S3 using the first discharge nozzle 310, the second discharge nozzle 320 may be in standby above the second priming roller 322, and when the second chemical solution 324 is discharged onto the third substrate S3 using the second discharge nozzle 320, the first discharge nozzle 310 may be in standby above the first priming roller 312.

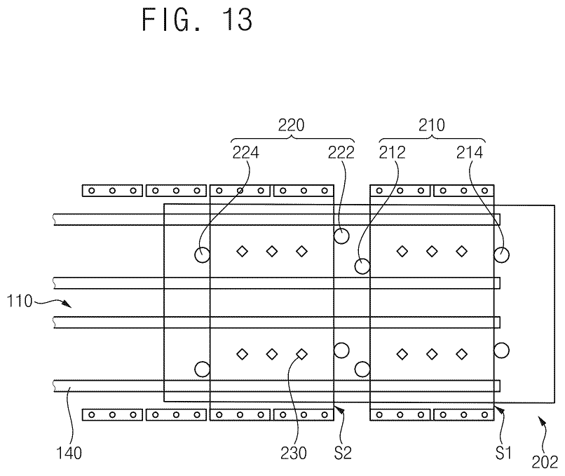

FIG. 13 is a plan view illustrating a substrate processing apparatus including a transfer device having a robot arm in according with example embodiments. The substrate processing apparatus may be substantially the same as the substrate processing apparatus described with reference to FIGS. 1 to 4 except for a configuration of a transfer device. Thus, same reference numerals may be used to refer to the same or like elements and any further repetitive explanation concerning the above elements will be omitted.

Referring to FIG. 13, a substrate processing apparatus may include a loading stage 202 to receive substrates for performing a coating process, a coating stage to apply chemicals on the substrates, an unloading stage to unload the substrates to the outside, and a transfer device 110 to transport the substrates.

In example embodiments, the transfer device 110 may transfer the substrates received from a transfer chamber 70 (see FIG. 1) to the loading stage 202. The transfer device 110 may sequentially transfer first and second substrates S1, S2 to the loading stage 202.

The transfer device 110 may include a robot arm 140 for transporting the first and second substrates S1, S2. The robot arm 140 may support lower surfaces of the first and second substrates S1, S2. The robot arm 140 may load the first and second substrates S1, S2 onto the loading stage 202 from one side of the loading stage 202. The lower surfaces of the first and second substrates S1, S2 may be spaced apart from the loading stage 202 by the robot arm 140. For example, the robot arm 140 may include a plurality of bars. The robot arm 140 may stably support the first and second substrates S1, S2 through the plurality of bars.

In example embodiments, the loading stage 202 may include a plurality of support pins 230 for receiving the first and second substrates S1, S2 from the robot arm 140, respectively. The plurality of support pins 230 may be provided between the plurality of support bars of the robot arm 140. The plurality of support pins 230 may be raised to support the lower surfaces of the first and second substrates S1, S2.

Hereinafter, a substrate processing method using the substrate processing apparatus of FIG. 13 will be described in detail.

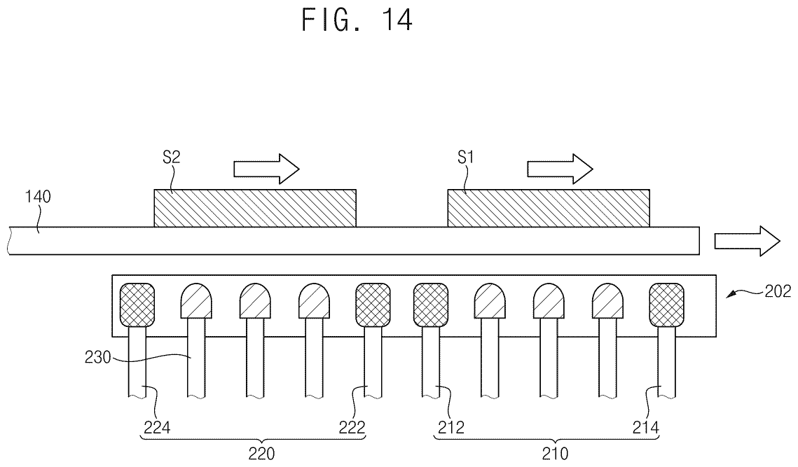

FIGS. 14 to 17 are views illustrating a step of placing first and second substrates through the robot arm of FIG. 13.

Referring to FIGS. 14 to 17, in a substrate processing method, first and second substrates S1, S2 may be loaded onto a loading stage 202 by a robot arm 140, and the first and second substrates S1, S2 may be aligned on the loading stage 202.

As illustrated in FIG. 14, first, the first and second substrates S1, S2 may be supported by the robot arm 140 through the plurality of bars and may be loaded from one side of the loading stage 202.

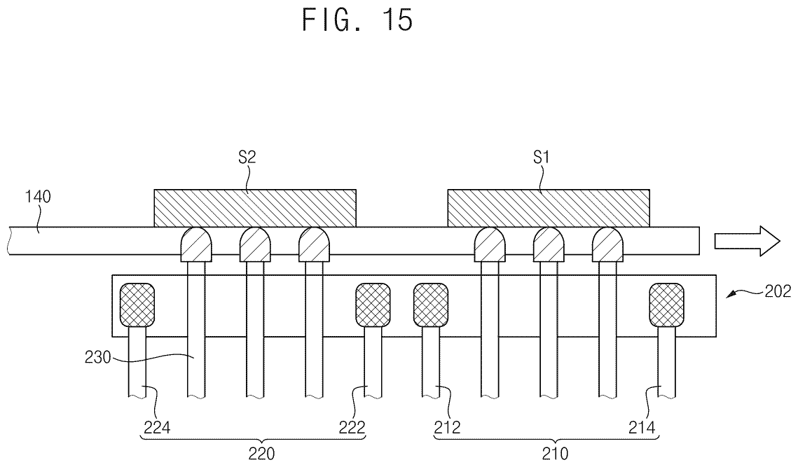

As illustrated in FIG. 15, then, a plurality of support pins 230 may be raised to support the lower surfaces of the first and second substrates S1, S2, respectively. The plurality of support pins 230 may be raised in a vertical direction between the plurality of support bars of the robot arm 140 to support the first and second substrates S1, S2.

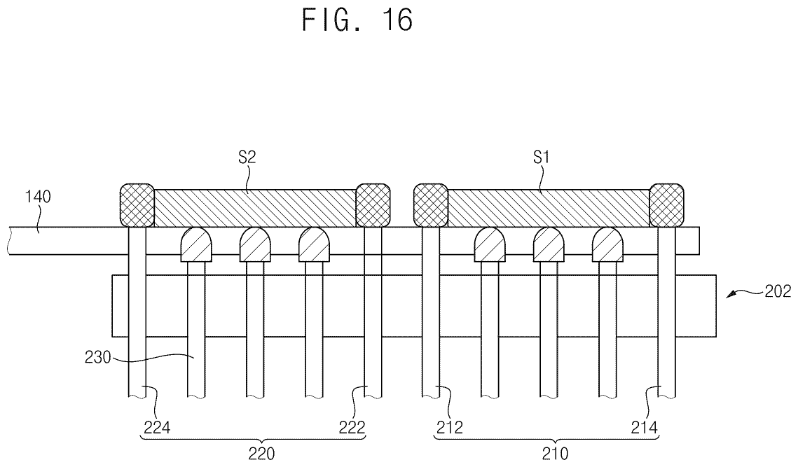

As illustrated in FIG. 16, first peripheral pins 214, first central pins 212, second peripheral pins 224, and second central pins 222 may be raised to align the first and second substrates S1, S2. The first peripheral pins 214 and the first central pins 212 may pressurize both end portions of the first substrate S1, respectively, to align the first substrate S1. The second peripheral pins 224 and the second central pins 222 may pressurize both end portions of the second substrate S2, respectively, to align the second substrate S2.

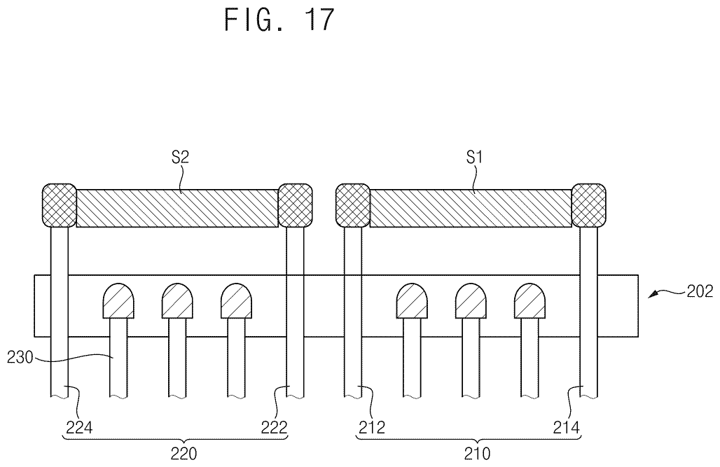

As illustrated in FIG. 17, after the first and second substrates S1, S2 are aligned, the first peripheral pins 214, the first central pins 212, the second peripheral pins 224, and the second central pins 222 may be lowered. When the robot arm 140 is used, the first and second substrates S1, S2 may be aligned simultaneously by the first peripheral pins 214, the first central pins 212, the second peripheral pins 224, and the second central pins 222. Accordingly, when the robot arm 140 is used, the process time (tact time) may be reduced.

Although example embodiments of the present disclosure have been described above, it will be understood by a person having ordinary skill in the art that various modifications and changes can be made to the present disclosure without departing from the idea and scope of the present disclosure as set forth in the appended claims.

What is claimed is:

1. A substrate processing apparatus, comprising:
an loading stage configured to receive first and second substrates, the loading stage including a first substrate alignment portion for aligning the first substrate and a second substrate alignment portion for aligning the second substrate, the second substrate alignment portion being arranged to be spaced apart from the first substrate alignment portion;
an coating stage configured to sequentially receive the first substrate and the second substrate from the loading stage, the coating stage including a first discharge nozzle for discharging a first chemical solution onto the first substrate and a second discharge nozzle for discharging a second chemical solution onto the second substrate; and
an unloading stage configured to sequentially unload the first substrate and the second substrate from the coating stage.

2. The substrate processing apparatus of claim 1, further comprising:
a transfer device configured to sequentially transfer the first and second substrates to the loading stage.

3. The substrate processing apparatus of claim 2, wherein the transfer device further comprises a plurality of rollers that are aligned on one side of the loading stage and rotate to move the first and second substrates.

4. The substrate processing apparatus of claim 2, wherein the transfer device further comprises a robot arm for transferring the first and second substrates, and
wherein the loading stage further comprises a plurality of support pins for receiving the first and second substrates from the robot arm, respectively.

5. The substrate processing apparatus of claim 1, wherein the first substrate alignment portion comprises:
a plurality of first central pins provided in a central region of the loading stage; and
a plurality of first peripheral pins provided in a first peripheral region adjacent to one side of the central region, and
wherein the second substrate alignment portion comprises:
a plurality of second central pins provided in the central region of the loading stage; and
a plurality of second peripheral pins provided in a second peripheral region adjacent to the other side opposite to the one side of the central region.

6. The substrate processing apparatus of claim 5, wherein the first and second central pins are arranged alternately with each other.

7. The substrate processing apparatus of claim 5, wherein the loading stage aligns a third substrate that is larger than each of the first and second substrates, through the first and second peripheral pins.

8. The substrate processing apparatus of claim 5, wherein the first and second central pins and the first and second peripheral pins are driven to move up and down and left and right to align each of the first and second substrates.

9. The substrate processing apparatus of claim 1, wherein when one of the first and second discharge nozzles is driven, the other discharge nozzle stops driving.

10. The substrate processing apparatus of claim 1, wherein the first discharge nozzle is provided adjacent to the loading stage, and the second discharge nozzle is provided adjacent to the unloading stage.

11. A substrate processing apparatus, comprising:
a transfer device configured to transfer first and second half plates in order to perform a coating process;
a loading stage configured to receive the first and second half plates from the transfer device, the loading stage including a first substrate alignment portion for aligning the first plate and a second substrate alignment portion for aligning the second plate, the second substrate alignment portion being arranged to be spaced apart from the first substrate alignment portion;
a coating stage configured to sequentially receive the first half plate and the second half plate from the loading stage, the coating stage including a first discharge nozzle for discharging a first chemical solution onto the first half plate and a second discharge nozzle for discharging a second chemical solution onto the second half plate; and
a loading stage configured to sequentially unload the first half plate and the second half plate from the loading stage.

12. The substrate processing apparatus of claim 11, wherein the transfer device further comprises a plurality of rollers that are aligned on one side of the loading stage and rotate to move the first and second half plates.

13. The substrate processing apparatus of claim 11, wherein the transfer device further includes a robot arm for transferring the first and second half plates, and
wherein the loading stage further includes a plurality of support pins for receiving the first and second half plates from the robot arm, respectively.

14. The substrate processing apparatus of claim 11, wherein the first substrate alignment portion comprises:
a plurality of first central pins provided in a central region of the loading stage; and
a plurality of first peripheral pins provided in a first peripheral region adjacent to one side of the central region, and
wherein the second substrate alignment portion comprises:
a plurality of second central pins provided in the central region of the loading stage; and
a plurality of second peripheral pins provided in a second peripheral region adjacent to the other side opposite to the one side of the central region.

15. The substrate processing apparatus of claim 14, wherein the first and second central pins are arranged alternately.

16. The substrate processing apparatus of claim 14, wherein the loading stage aligns a substrate that is larger than each of the first and second half plates, through the first and second peripheral pins.

17. The substrate processing apparatus of claim 14, wherein the first and second central pins and the first and second peripheral pins are driven to move up and down and left and right to align each of the first and second half plates.

18. The substrate processing apparatus of claim 11, wherein when one of the first and second discharge nozzles is driven, the other discharge nozzle stops driving.

19. The substrate processing apparatus of claim 11, wherein the first discharge nozzle is provided adjacent to the loading stage, and the second discharge nozzle is provided adjacent to the unloading stage.

20. A substrate processing apparatus, comprising:
a transfer device configured to transfer first and second half plates in order to perform a coating process;
a loading stage configured to receive the first and second half plates from the transfer device, the loading stage having a central region and first and second peripheral regions in both sides of the central region, the loading stage including a first substrate alignment portion and a second substrate alignment portion, wherein the first substrate alignment portion aligns the first half plate through a plurality of first central pins provided in the central region and a plurality of first peripheral pins provided in the first peripheral region, wherein the second substrate alignment portion aligns the second half plate through a plurality of second central pins provided in the central region and a plurality of second peripheral pins provided in the second peripheral region, the second central pins being arranged alternately with the first central pins;
a coating stage configured to sequentially receive the first and second half plates from the loading stage, the coating stage having a first discharge nozzle for discharging a first chemical solution onto the first half plate and a second discharge nozzle for discharging a second chemical solution onto the second half plate, the coating stage being configured to selectively drive one of the first and second discharge nozzles; and
an unloading stage configured to sequentially unload the first half plate and the second half plate from the coating stage to the outside.
